(19) United States
(12) Patent Application Publication
(10) Pub. No.: US 2012/0326733 A1
(43) Pub. Date: Dec. 27, 2012

(54) LIQUID SENSOR

(76) Inventor: Nobuhiro Kato, Tokai-shi (JP)

(21) Appl. No.: 13/524,879

(22) Filed: Jun. 15, 2012

(30) Foreign Application Priority Data
Jun. 21, 2011 (JP) 2011-137287

(51) Int. Cl. G01N 27/22; G01R 27/26

(52) U.S. Cl. 324/674

(57) ABSTRACT

A liquid sensor may comprise an electrode unit and a calculating unit. The electrode unit may be capable of respectively connecting with a first oscillating unit and a second oscillating unit. The first oscillating unit may output a first frequency signal having an amplitude of Vin1 and an angular velocity of ω1. The second oscillating unit may output a second frequency signal having an amplitude of Vin2 and an angular velocity of ω2. The calculating unit may calculate a capacitance C1 of the electrode unit.

### CROSS-REFERENCE TO RELATED APPLICATION

This application claims priority to Japanese Patent Application No. 2011-137287 filed on Jun. 21, 2011, the contents of which are hereby incorporated by reference into the present application.

### TECHNICAL FIELD

The present application relates to a liquid sensor for detecting a liquid property.

### DESCRIPTION OF RELATED ART

US Patent Application Publication No. 2004-251919 A1 and US Patent Application Publication No. 2003-117153 A1 disclose liquid sensors provided with an electrode pair disposed in a fuel. In these liquid sensors, a plurality of kinds of frequency signals is successively inputted to the pair of electrodes. The concentration of an alcohol or the like in the fuel is determined using a plurality of kinds of output signals outputted from the electrode pair.

### SUMMARY

In these liquid sensors, capacitance of the electrode pair changes depending on the concentration of a specific component (in US Patent Application Publication No. 2004-251919 A1 and US Patent Application Publication No. 2003-117153 A1, the specific component is an alcohol) in the liquid. Therefore, the concentration of the specific component is determined by calculating the capacitance of the electrode pair using the signals inputted to the electrode pair and signals outputted from the electrode pair. However, the capacitance sometimes cannot be adequately determined by simply using the signals inputted to the electrode pair and the signals outputted from the electrode pair. The present specification provides a liquid sensor that may adequately calculate capacitance of an electrode pair.

The present application discloses a liquid sensor for detecting a liquid property. The liquid sensor comprises an electrode unit and a calculating unit. The electrode unit comprises a first electrode pair to be disposed within liquid. The calculating unit is configured to calculate a capacitance of the electrode unit by using an output signal outputted from the electrode unit. The electrode unit is configured capable of respectively connecting with a first oscillating unit and a second oscillating unit. The first oscillating unit is configured to output a first frequency signal having an amplitude of Vin1 and an angular velocity of ω1. The second oscillating unit is configured to output a second frequency signal having an amplitude of Vin2 and an angular velocity of ω2. The calculating unit calculates a capacitance C1 of the electrode unit by solving a below formula:

$$C 1 = \sqrt{\frac{\frac{1}{Z {1}^{2}} - \frac{1}{Z {2}^{2}}}{( ω {1}^{2} - ω {2}^{2} )}}$$

The above formula includes the followings: Z1=R1/(Vin1/Vout1−1), Z2=R2/(Vin2/Vout2−1), Vout1 is an amplitude of the first output signal, Vout2 is an amplitude of the second output signal, R1 is a resistance value between the electrode unit and the first oscillating unit, and R2 is a resistance value between the electrode unit and the second oscillating unit.

### BRIEF DESCRIPTION OF DRAWINGS

FIG. 1 shows schematically a sensor system.

FIG. 2 is a schematic front view of the electrode unit.

FIG. 3 is a cross-sectional view taken along the III-III line in FIG. 2.

FIG. 4 is a cross-sectional view taken along the IV-IV line in FIG. 2.

FIG. 5 is a graph illustrating changes in the amplitude of an output signal depending on the frequency of an input signal.

FIG. 6 is a schematic front view of the electrode unit of a variant.

FIG. 7 is a cross-sectional view of the electrode unit of a variant.

FIG. 8 is a cross-sectional view of the electrode unit of a variant.

FIG. 9 is a cross-sectional view of the electrode unit of a variant.

FIG. 10 is a cross-sectional view of the electrode unit of a variant.

### DETAILED DESCRIPTION

Hereinbelow, some of primary features of the embodiments explained below will be listed. The technical features listed below are independent from one another, of which technical utility may be enjoyed separately or in combinations; it should be noted that the teachings herein are not limited to the combinations presented in the claims as originally filed.

(First Feature) A liquid sensor may further comprise a first resistor and a second resistor. The first resistor may be disposed between a first oscillating unit and an electrode unit, and have a resistance value R1. The second resistor may be disposed between a second oscillating unit and the electrode unit, and have a resistance value R2 that is different from the R1.

By adjusting the resistance value of the first resistor, an amplitude (that is, Vout1) of an output signal may be adjusted in the case where a signal from the first oscillating unit is supplied to the electrode unit. Likewise, by adjusting the resistance value of the second resistor, the amplitude (that is, Vout2) of the output signal may be adjusted in the case where a signal from the second oscillating unit is supplied to the electrode unit. With such a configuration, the amplitude of each output signal may be adjusted by separately adjusting the resistance values of the first and second resistors.

(Second Feature) The resistance value R1 may be larger than the resistance value R2.

If a configuration is used in which the resistance values of the first and second resistors are equal to each other (that is, R1=R2), the amplitude Vout1 of the output signal in the case where a signal is supplied from the first oscillating unit becomes larger than the amplitude Vout2 of the output signal in the case where a signal is supplied from the second oscillating unit. In a case where the difference in the amplitude between the output signals increases, it is necessary to provide separate circuits for processing (amplitude processing or the like) the respective output signals. By making R1 larger than R2, it is possible to bring Vout1 and Vout2 close to each other. As a result, it is not necessary to provide separate circuits for processing (amplitude processing or the like) the respective output signals.

(Third Feature) The electrode unit may further comprise a second electrode pair. The first electrode pair and the second electrode pair may be layered. One of the second electrode pair may be connected with one of the first electrode pair. The other of the second electrode pair may be connected with the other of the first electrode pair.

With such a configuration, capacitance C1 of the electrode unit can be increased. As a result, the effect of resistance of the liquid on impedances Z1, Z2 may be reduced.

(Fourth Feature) The electrode unit may further comprise a shield electrode disposed adjacent to an electrode of the first electrode pair that is connected to at least one oscillating unit of the first oscillating unit, the second oscillating unit or a combination thereof. The shield electrode may be configured to be connected to the one oscillating unit without any resistance unit intervened between the shield electrode and the one oscillating unit. The shield electrode may be connected to the oscillating unit without any resistance unit intervened therebetween.

With such a configuration, an adequate signal can be inputted to the shield electrode.

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved liquid sensors, as well as methods for using and manufacturing the same.

Moreover, combinations of features and steps disclosed in the following detail description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

### Embodiment

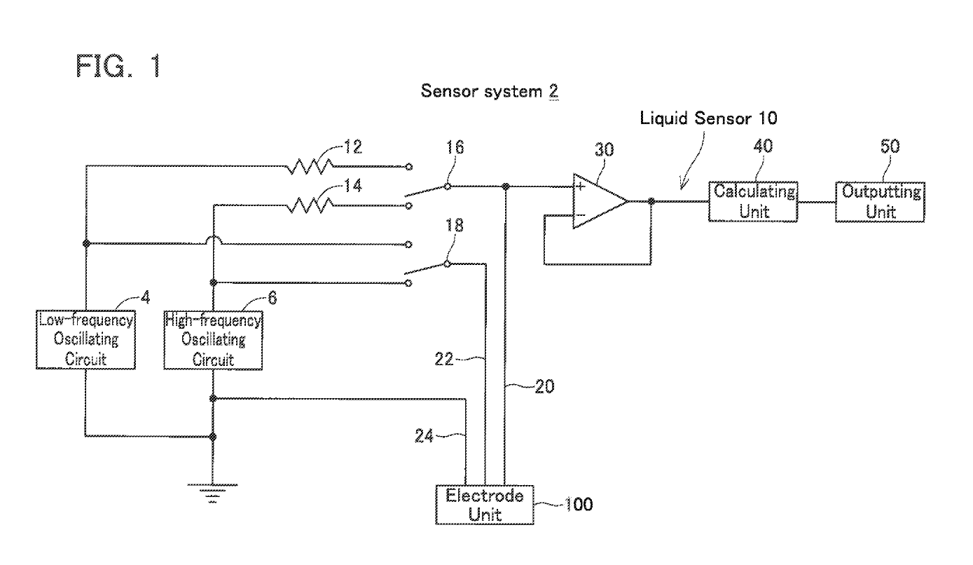

As shown in FIG. 1, a sensor system 2 comprises a liquid sensor 10, a low-frequency oscillating circuit 4, and a high-frequency oscillating circuit 6. The sensor system 2 is used for measuring the concentration of ethanol in a mixed fuel of gasoline and ethanol.

The low-frequency oscillating circuit 4 generates a low-frequency (e.g., 10 Hz to 50 kHz) signal voltage from power supplied from a power supply (not shown in the figure). The high-frequency oscillating circuit 6 generates a high-frequency (e.g., 500 kHz to 10 MHz) signal voltage from power supplied form the same power supply (not shown in the figure) as that supplying power to the low-frequency oscillating circuit 4. The amplitude of the low-frequency signal voltage is represented by Vin1, and the amplitude of the high-frequency signal voltage is represented by Vin2. The Vin1 may be equal to the Vin2, or may be different from the Vin2.

The liquid sensor 10 comprises two resistors 12, 14, an electrode unit 100, an operational amplifier 30, a calculating unit 40, and an outputting unit 50.

The first resistor 12 is connected to the low-frequency oscillating circuit 4. The second resistor 14 is connected to the high-frequency oscillating circuit 6. The resistance value R1 (e.g., 10 kΩ to 50 kΩ) of the first resistor 12 is larger than the resistance value R2 (e.g., 1 kΩ to 10 kΩ) of the second resistor 14.

The two resistors 12, 14 are connected through a switch 16 to a conductive wire 20. The conductive wire 20 is connected to a signal electrode 104 of the below-described electrode unit 100. Thus, a signal voltage from either of the two oscillating circuits 4, 6 is inputted to the signal electrode 104 by switching the switch 16.

The two oscillating circuits 4, 6 are connected through a switch 18 to a conductive wire 22. The conductive wire 22 is connected to a shield electrode 102 of the below-described electrode unit 100. Thus, a signal voltage from either of the two oscillating circuits 4, 6 is inputted to the shield electrode 102 by switching the switch 18. The switch 18 is synchronized with the switch 16. In a state that the switch 16 is connected to the low-frequency oscillating circuit 4, the switch 18 is also connected to the low-frequency oscillating circuit 4, and in a state that the switch 16 is connected to the high-frequency oscillating circuit 6, the switch 18 is also connected to the high-frequency oscillating circuit 6.

A resistor is not disposed between the two oscillating circuits 4, 6 and the shield electrode 102. Strictly speaking, the resistance between the two oscillating circuits 4, 6 and the shield electrode 102 is only the resistance of the conductive wire connecting the two oscillating circuits 4, 6 and the shield electrode 102. In other words, the resistance value between the low-frequency oscillating circuit 4 and the shield electrode 102 is less than the resistance value between the low-frequency oscillating circuit 4 and the signal electrode 104, and the resistance value between the high-frequency oscillating circuit 6 and the shield electrode 102 is less than the resistance value between the high-frequency oscillating circuit 6 and the signal electrode 104.

The conductive wire 20 is connected to the calculating unit 40 through the operational amplifier 30. The calculating unit 40 stores a concentration database in which a capacitance is associated with an ethanol concentration. The concentration database has been stored in the calculating unit 40 in advance. The relationship between the capacitance of the electrode unit 100 and the ethanol concentration is stored for a plurality of kinds of mixed fuels with different ethanol concentrations in the concentration database. The concentration database can be created, for example, by the following sequence. Thus, a manufacturer of the sensor system 2 prepares a plurality of kinds of mixed fuels with different ethanol concentrations. Then, the manufacturer immerses the electrode unit 100 into one kind of the mixed fuel and successively inputs signal voltages from the two oscillating circuits 4, 6. The manufacturer measures the amplitude of the output signal outputted from the electrode unit 100. The amplitude of the output signal in the case where a signal voltage from the low-frequency oscillating circuit 4 is inputted to the electrode unit 100 is represented by “Vout1”, and the amplitude of the output signal in the case where a signal voltage from the high-frequency oscillating circuit 6 is inputted to the electrode unit 100 is represented by “Vout2”. To be exact, the amplitude of the signal after the output signal from the electrode unit 100 has been amplified by the operational amplifier 30 is represented by “Vout1” and “Vout2”. The angular velocity of the signal voltage of the low-frequency oscillating circuit 4 is col, and the angular velocity of the signal voltage of the high-frequency oscillating circuit 6 is ω2.

The manufacturer calculates the impedances Z1, Z2 in the electrode unit 100 by calculating Z1=R1/(Vin1/Vout1−1) and Z2=R2/(Vin2/Vout2−1). Then, the capacitance (represented hereinbelow by “C1”) of the electrode unit 100 is calculated by solving a formula below. Since the concentration of ethanol in the mixed fuel relating to the measurements is already known, the relationship between the calculated capacitance C1 and the ethanol concentration corresponding to the capacitance can be determined.

$$C 1 = \sqrt{\frac{\frac{1}{Z {1}^{2}} - \frac{1}{Z {2}^{2}}}{( ω {1}^{2} - ω {2}^{2} )}} \qquad ( 1 )$$

The manufacturer determines the relationship between the capacitance of the electrode unit 100 and ethanol concentration by calculating the capacitance C1 for each of the plurality of kinds of prepared mixed fuels. In a variant, the manufacturer of the sensor system 2 may create a formula representing the relationship between the capacitance of the electrode unit 100 and ethanol concentration and store the formula in the calculating unit 40.

The output signal outputted from the electrode unit 100 is supplied to the calculating unit 40 via the operational amplifier 30. The calculating unit 40 determines the concentration of ethanol in the fuel by using the supplied output signal and the concentration database. The calculating unit 40 supplies the determined ethanol concentration to the outputting unit 50. The outputting unit 50 supplies the ethanol concentration acquired from the calculating unit 40 to an output (e.g., a display or another device (fuel supply device)).

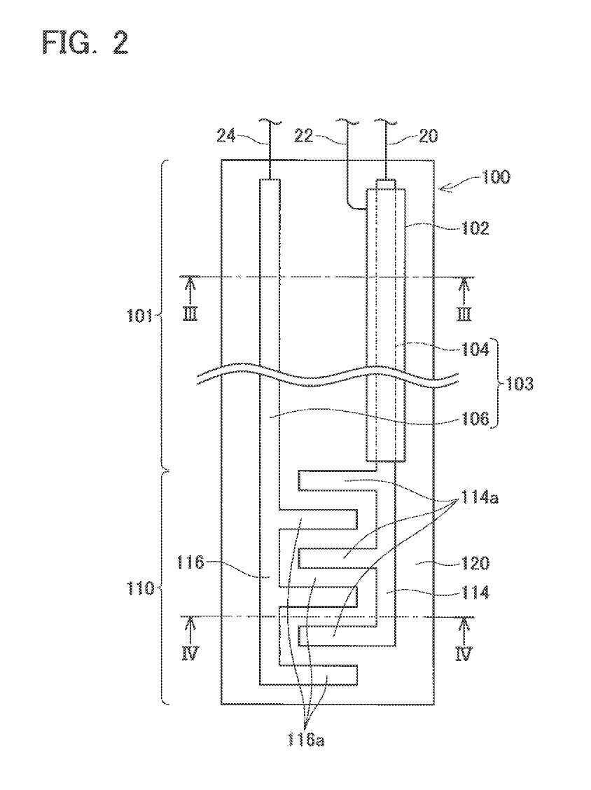

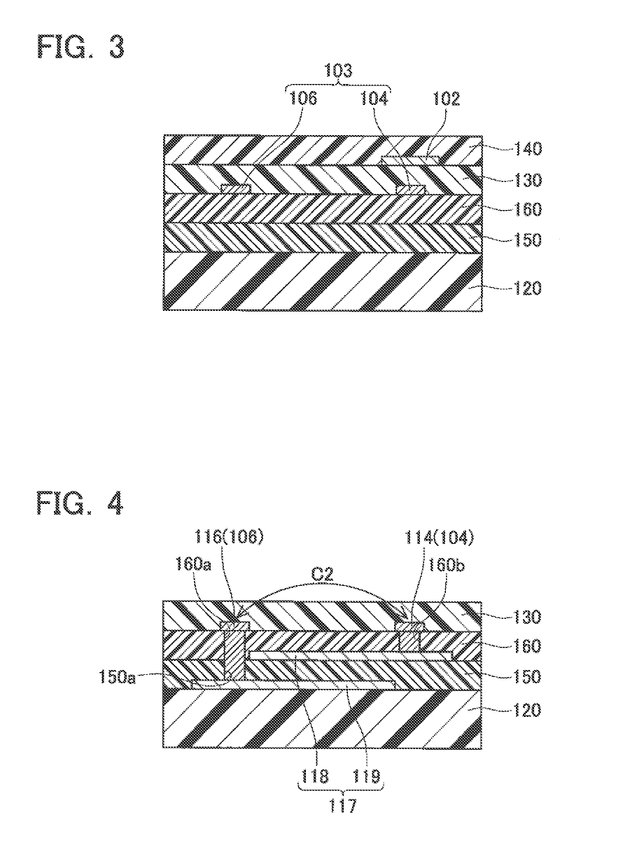

FIGS. 2, 3, and 4 show the electrode unit 100. In FIG. 2, insulating films 130, 140 shown in FIGS. 3 and 4 are omitted. The electrode unit 100 is disposed within a fuel tank. The electrode unit 100 is provided with a conductive portion 101 and a detection portion 110 disposed at the lower side of the conductive portion 101. The detection portion 110 is disposed at the lower side of the electrode unit 100 so that the entire detection portion 110 is immersed at all times in the mixed fuel inside the fuel tank. As a result, capacitance C3 of the detection portion 110 is prevented from changing due to the changes in the amount of the mixed fuel around the detection portion 110.

As shown in FIG. 2, the electrode portion 100 comprises a first electrode pair 103. The first electrode pair 103 comprises a signal electrode 104 and a ground electrode 106. The two electrodes 104, 106 both extend from the upper end of the conductive portion 101 to the lower end of the detection portion 110. The two electrodes 104, 106 are arranged on the same plane.

The two electrodes 104, 106 positioned in the conductive portion 101 extend linearly in a longitudinal direction (up-down direction in FIG. 2) of the electrode unit 100. An upper end of the signal electrode 104 is connected to the conductive wire 20. The ground electrode 106 is grounded by a conductive wire 24.

The signal electrode 104 positioned in the detection portion 110 comprises an electrode base 114 which continues to the signal electrode 104 positioned in the conductive portion 101 and extends linearly in the longitudinal direction of the electrode unit 100. A plurality (three in FIG. 2) of electrode portions 114a extending toward an electrode base 116 of the ground electrode 106 is connected to the electrode base 114.

The ground electrode 106 positioned in the detection portion 110 comprises the electrode base 116 which continues to the ground electrode 106 positioned in the conductive portion 101 and extends linearly in the longitudinal direction of the electrode unit 100. A plurality (three in FIG. 2) of electrode portions 116a extending toward the electrode base 114 is connected to the electrode base 116. The number of the electrode portions 116a is equal to that of the electrode portions 114a. The plurality of electrode portions 114a and the plurality of electrode portions 116a are disposed alternately, starting from the electrode portion 114a and ending with the electrode portion 116a, from an upper side of the electrode unit 100. The adjacent electrode portions 114a and electrode portions 116a are separated from each other.

As shown in FIG. 4, in the detection portion 110, a second electrode pair 117 is disposed parallel to the two electrodes 104, 106 (that is, the first electrode pair 103). That is, the second electrode pair 117 and the first electrode pair 103 are layered. The second electrode pair 117 comprises a signal electrode 118 and a ground electrode 119. The two electrodes 118, 119 are in the form of rectangular flat plates of the same shape. The length of the two electrodes 118, 119 (i.e., the second electrode pair 117) in the longitudinal direction of the electrode unit 100 is substantially equal to the length of the detection portion 110. The two electrodes 118, 119 are disposed at the same position in the longitudinal direction of the electrode unit 100 and are displaced with respect to each other in a direction perpendicular to the longitudinal direction of the electrode unit 100.

An insulating film 160 is disposed between the signal electrode 118 and the first electrode pair 103. The signal electrode 118 is electrically connected to the electrode base 114 of the signal electrode 104 via a through hole 160b provided in the insulating film 160. The signal electrode 118 is disposed on an insulating film 150.

The two insulating films 150, 160 are disposed between the ground electrode 119 and the first electrode pair 103. The ground electrode 119 is electrically connected to the electrode base 116 of the ground electrode 106 via a through hole 150a provided in the insulating film 150 and a through hole 160a provided in the insulating film 160. The base electrode 119 is disposed on an insulating plate 120. That is, the second electrode pair 117 opposes the first electrode pair 103 with the insulating films 150, 160 in between.

The insulating plate 120 has a constant thickness (length in the upper-down direction in FIG. 3) and extends from one end to the other end of the electrode unit 100 in the longitudinal direction thereof. The insulating film 150 extends from one end to the other end of the electrode unit 100 in the longitudinal direction thereof on one surface (upper surface in FIG. 3) of the insulating plate 120. The insulating film 160 extends from one end to the other end of the electrode unit 100 in the longitudinal direction thereof on one surface (upper surface in FIG. 3) of the insulating film 150. As shown in FIG. 3, the first electrode pair 103 is attached to one surface (upper surface in FIG. 3) of the insulating film 160 positioned in the conductive portion 101.

The shield electrode 102 is disposed parallel to the signal electrode 104 on the surface (upper surface in FIG. 3) on the side of the signal electrode 104 opposite that of the insulating plate 120 in the conductive portion 101. The length of the shield electrode 102 in the longitudinal direction of the electrode unit 100 is substantially equal to the length of the signal electrode 104 of the conductive portion 101. The shield electrode 102 faces the signal electrode 104, with the insulating film 130 being interposed therebetween.

The operation of the sensor system 2 will be explained below. First, the switches 16 and 18 of the liquid sensor 10 are connected to the low-frequency oscillating circuit 4. As a result, a signal voltage from the low-frequency oscillating circuit 4 is inputted to the signal electrode 104 and the shield electrode 102.

As shown in FIG. 4, in a case where a signal voltage is supplied to the signal electrode 104, charges of capacitance C2 is accumulated between the signal capacitance 104 and the ground electrode 106 in the detection portion 110. The mixed fuel is present at a position where the charge of capacitance C2 is accumulated. The capacitance C2 changes depending on the ethanol concentration of the mixed fuel. Therefore, the ethanol concentration in the mixed fuel can be determined by determining the capacitance C2.

Since the switch 16 and the switch 18 are synchronized, in a case where a signal voltage is supplied to the signal electrode 104, a signal voltage of the same frequency as that of the signal electrode 104 is also supplied to the shield electrode 102. As a result, the accumulation of charge in the first electrode pair 103 in the conductive portion 101 is prevented. The conductive portion 101 is positioned higher than the detection portion 110, more specifically an upper side of the fuel tank. Therefore, in the conductive portion 101, the length of the portion immersed in the mixed fuel changes depending on the amount of mixed fuel inside the fuel tank. As a result, in the configuration in which the charge accumulates in the first electrode pair 103 of the conductive portion 101, the capacitance C2 of the electrode unit 100 changes depending on the amount of mixed fuel within the fuel tank. In the configuration of the electrode unit 100, by providing the shield electrode 102, it is possible to prevent the capacitance C2 from changing under the effect of the amount of mixed fuel inside the fuel tank.

Further, in a case where a signal voltage is inputted to the signal electrode 104, the signal voltage is also inputted to the signal electrode 118 connected to the signal electrode 104. As a result, charges of capacitance C3 accumulates between the signal electrode 118 and the ground electrode 119. The capacitance C3 is determined by the insulating film 150 between the signal electrode 118 and the ground electrode 119. Thus, the capacitance C3 is constant regardless of the ethanol concentration in the mixed fuel. In addition, in a case where a signal voltage is applied to the signal electrode 104, charges are also accumulated between the signal electrode 118 and the ground electrode 106. However, since no mixed fuel is present between the signal electrode 118 and the ground electrode 106, the capacitance between the signal electrode 118 and the ground electrode 106 is constant regardless of the ethanol concentration in the mixed fuel.

While the signal voltage from the low-frequency oscillating circuit 4 is inputted to the signal electrode 104, the output signal outputted from the signal electrode 104 is amplified by the operational amplifier 30 and supplied to the calculating unit 40. As clearly follows from the explanation above, in the case where a signal voltage is inputted to the signal electrode 104, the charges of capacitance C2 are accumulated between the signal electrode 104 and the ground electrode 106, and the charges of capacitance C3 are accumulated between the signal electrode 118 and the ground electrode 119. Therefore, the capacitance C1 accumulated in the electrode unit 100 is a sum of the capacitance C2 and the capacitance C3. Therefore, the output signal outputted from the signal electrode 104 corresponds to the capacitance C2 and the capacitance C3.

The switches 16, 18 of the liquid sensor 10 are then switched to the high-frequency oscillating circuit 6 side. As a result, a signal voltage outputted from the high-frequency oscillating circuit 6 is inputted to the signal electrode 104 and the shield electrode 102.

While the signal voltage from the high-frequency oscillating circuit 6 is inputted to the signal electrode 104, the output signal outputted from the signal electrode 104 is amplified by the operational amplifier 30 and supplied to the calculating unit 40.

In a case where the calculating unit 40 acquires the two kinds of output signals, the calculating unit 40 calculates the impedances Z1, Z2 of the electrode unit 100. The Z1 is calculated by solving the formula Z1=R1/(Vin1/Vout1−1). The Z2 is calculated by solving the formula Z2=R2/(Vin2/Vout2−1). The Vout1 is the amplitude of the signal obtained by amplification with the operation amplifier 30 of the output signal outputted from the signal electrode 104 while the signal voltage from the low-frequency oscillating circuit 4 has been inputted to the signal electrode 104. The Vout2 is the amplitude of the signal obtained by amplification with the operation amplifier 30 of the output signal outputted from the signal electrode 104 while the signal voltage from the high-frequency oscillating circuit 6 has been inputted to the signal electrode 104.

In the case where the impedances Z1, Z2 are calculated, the capacitance C1 is calculated by solving the formula below. As has been mentioned hereinabove, the capacitance C1 is the sum total of the capacitance C2 of the first electrode pair 103 and the capacitance C3 of the second electrode pair 117.

$$C 1 = \sqrt{\frac{\frac{1}{Z {1}^{2}} - \frac{1}{Z {2}^{2}}}{( ω {1}^{2} - ω {2}^{2} )}} \qquad ( 2 )$$

The calculating unit 40 then determines the ethanol concentration by using the calculated capacitance C1 and the concentration database. The calculating unit 40 outputs the determined ethanol concentration to the outputting unit 50.

The impedance Z1 and capacitance C1 satisfy the following relationship: (ω1×C1)²+(1/R3)²=(1/Z1)². Here, R3 is a resistance value of the mixed fuel. The resistance value (that is, conductivity) of the mixed fuel varies depending on the degree of oxidation of the mixed fuel. Therefore, where the ethanol concentration is determined by using only the output signal, that is, without consideration for the variations in the resistance value of the mixed fuel, the accurate ethanol concentration cannot be determined.

The liquid sensor 10 calculates the capacitance C1 by using the output signal obtained by inputting two kinds of signal voltages that differ in frequency into the electrode unit 100. Therefore, the capacitance C1 of the electrode unit 100 can be adequately calculated without using the resistance value of the mixed fuel. As a result, the adequate ethanol concentration can be determined.

In general, in a case where the resistance value of the liquid that is the detection target is R3, the impedance Z1 obtained while a signal from the first oscillating unit is inputted to the electrode unit satisfies the relationship: (ω1×C1)²+(1/R3)²=(1/Z1)². Likewise, the impedance Z2 obtained while a signal from the second oscillating unit is inputted to the electrode unit satisfies the relationship: (ω2×C1)²+(1/R3)²=(1/Z2)². Here, the resistance value (that is, R3) of the liquid is a variable that is changed by oxidation of the liquid etc. Since the resistance value R3 of the liquid is not determined even when the relational expressions, for example Z1=R1/(Vin1/Vout1−1) and (ω1×C1)²+(1/R3)²=(1/Z1)², obtained by inputting one frequency signal to the electrode unit are used, the capacitance C1 of the electrode unit cannot be calculated. In the abovementioned liquid sensor, the capacitance C1 of the electrode unit is calculated by solving with the calculating unit the abovementioned formulas derived from the relational expressions obtained by inputting a signal from the first oscillating unit and a signal from the second oscillating unit. With such a configuration, the capacitance C1 of the electrode unit may be calculated adequately regardless of the resistance value R3 of the liquid.

In the liquid sensor 10, the resistor 12 is provided between the low-frequency oscillating circuit 4 and the electrode unit 100, and the resistor 14 is provided between the high-frequency oscillating circuit 6 and the electrode unit 100. With such a configuration, the resistance value between the low-frequency oscillating circuit 4 and the electrode unit 100 and the resistance value between high-frequency oscillating circuit 6 and the electrode unit 100 can be set separately from each other. As a result, the amplitude of the output signal outputted from the electrode unit 100 while the signal voltage is supplied from the low-frequency oscillating circuit 4 to the electrode unit 100 and the amplitude of the output signal outputted from the electrode unit 100 while the signal voltage is supplied from the high-frequency oscillating circuit 6 to the electrode unit 100 can be adjusted separately from each other.

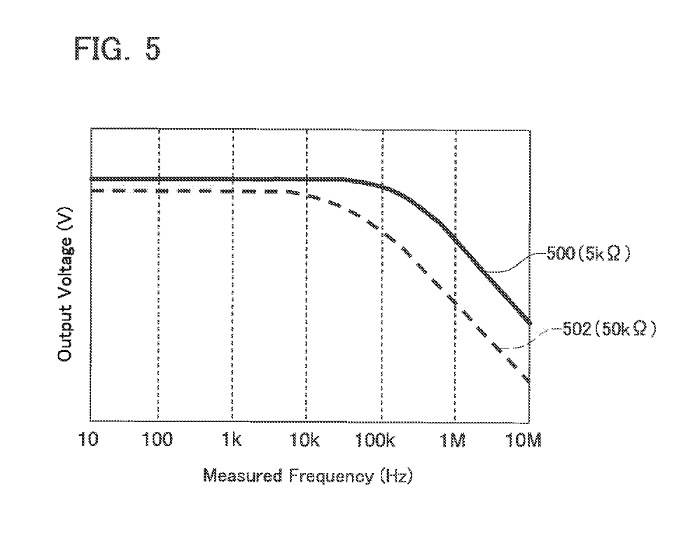

FIG. 5 is a graph illustrating the relationship between the frequency of the input signal (abscissa) and the amplitude (that is, output voltage) of the output signal (ordinate). A result 500 is a measured value of the output voltage in a case where the resistance between the oscillating circuit and the electrode unit 100 is 5 kΩ, and a result 502 is a measured value of the output voltage in a case where the resistance between the oscillating circuit and the electrode unit 100 is 50 kΩ. In a case where the frequency of the input signal increases, the output voltage decreases both when the resistance value is 5 kΩ and when it is 50 kΩ.

For example, when the resistance value between the low-frequency oscillating circuit 4 and the electrode unit 100 is equal to the resistance value between the high-frequency oscillating circuit 6 and the electrode unit 100, the difference between the output voltage obtained when an input signal is supplied from the low-frequency oscillating circuit 4 to the electrode unit 100 and the output voltage obtained when an input signal is supplied from the high-frequency oscillating circuit 6 to the electrode unit 100 becomes large. In this case, the output signal cannot be adequately processed without providing an output signal processing circuit for each output signal. In the liquid sensor 10, the resistance value R1 of the first resistor 12 connected to the low-frequency oscillating circuit 4 is larger than the resistance value R2 of the second resistor 14 connected to the high-frequency oscillating circuit 6. Therefore, the value of the output voltage in the case where the input signal is supplied from the low-frequency oscillating circuit 4 to the electrode unit 100 can be reduced. As a result, the difference in output voltage can be reduced.

In the electrode unit 100, the second electrode pair 117 is provided in parallel with the first electrode pair 103. With such a configuration, the capacitance of the electrode unit 100 can be increased. Further, the capacitance C3 of the second electrode pair 117 is not affected by the mixed fuel and can be determined by the insulating film 150 located between the signal electrode 118 and the ground electrode 119. As a result, the effect of the resistance value (conductivity) of the mixed fuel on the output voltage in the case where the input signal is supplied from the high-frequency oscillating circuit 6 can be reduced. The value of the output voltage in the case where the input signal is supplied from the low-frequency oscillating circuit 4 is practically unaffected by the resistance value (conductivity) of the mixed fuel. Further, the second electrode pair 117 is provided by layering on the first electrode pair 103. As a result, by providing the second electrode pair 117, it is possible to suppress the increase of the electrode unit 100 in size.

Charges are sometimes accumulated, for example, between the shield electrode 102 and the fuel tank connected to ground. In this case, if the configuration is used in which the signal outputted from the operation amplifier 30 is inputted to the shield electrode 102, the amplitude of the signal outputted from the operational amplifier 30 changes under the effect of capacitance generated at the shield electrode 102. Therefore, the capacitance in the detection portion 110 cannot be adequately calculated. Meanwhile, in the above-described electrode unit 100, the shield electrode 102 inputs signals from the oscillating circuits 4, 6 identical to the signal electrode 104. With such a configuration, the effect of changes caused by the capacitance generated in the shield electrode 102 on the changes in the output signal can be reduced by comparison with the case where the signal outputted from the operational amplifier 30 is inputted to the shield electrode 102. Furthermore, no resistor is provided between the shield electrode 102 and either of the two oscillating circuits 4, 6. As a result, even when a capacitance is generated, for example, between the shield electrode 102 and the electrically connected fuel tank, the voltage applied to the shield electrode 102 can be prevented from changing. As a result, the effect of changes caused by the capacitance generated at the shield electrode 102 on the changes in the output signal can be further decreased.

The embodiments of the present invention are described in detail above, but those are merely exemplary embodiments that place no limitation on the claims. The techniques described in the claims also include various changes and modifications of the above-described specific examples.

### Variation Examples

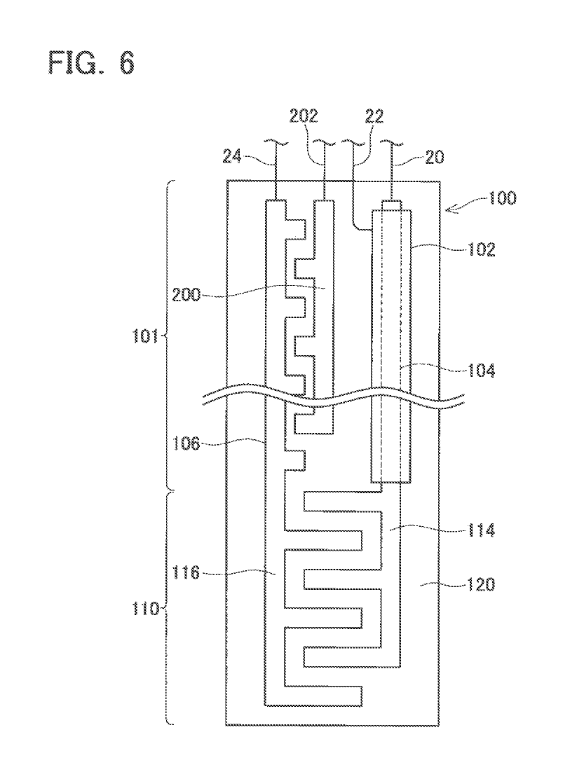

(1) As shown in FIG. 6, the electrode unit 100 may comprise a signal electrode 200 facing the ground electrode 106 in the conductive portion 101. The signal electrode 200 may be connected by the conductive wire 202 to the high-frequency oscillating circuit 6. With such a configuration, the amount of fuel in the fuel tank can be detected using an output signal outputted from the electrode unit 100.

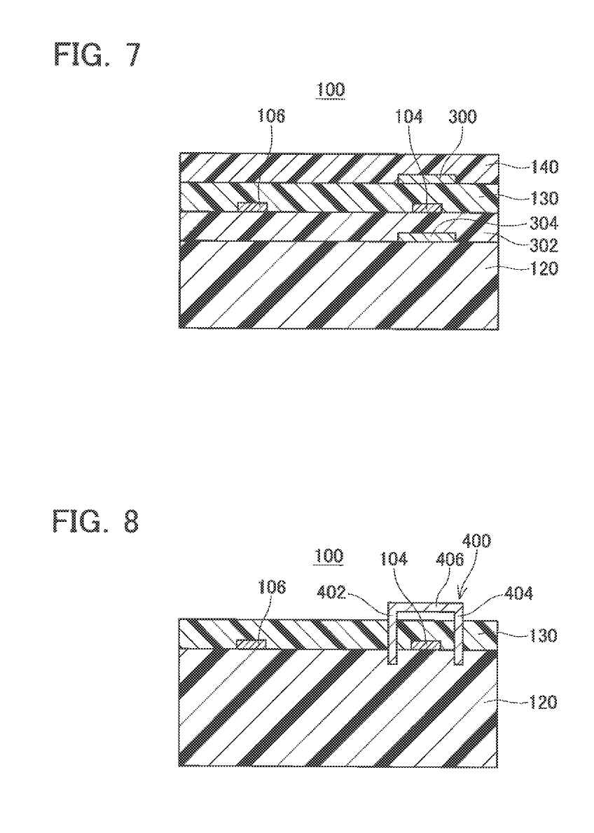

(2) The configuration of the shield electrode disposed around the signal electrode 104 is not limited to the shield electrode 102. As shown in FIG. 7, a shield electrode 300 may be disposed opposite the signal electrode 104, with the insulating film 130 being interposed therebetween. The shield electrode 300 may have the same shape as the shield electrode 102 and be disposed at the same position as the shield electrode 102 with respect to the signal electrode 104. Further, a shield electrode 304 may be also provided on the side (lower side in FIG. 7) opposite that of the shield electrode 300 so as to sandwich the signal electrode 104. The shield electrode 304 may face the signal electrode 104, with an insulating layer 302 being interposed therebetween. The shield electrode 304 may have the same shape as the shield electrode 300 and be disposed at a position facing the signal electrode 300.

(3) As shown in FIG. 8, a shield electrode 400 may be provided instead of the shield electrode 102. The shield electrode 400 may comprise three flat portions 402 to 406. Each of the three flat portions 402 to 406 may be disposed parallel to the signal capacitance 104 in the conductive portion 101. Each of the three flat portions 402 to 406 may have a length substantially equal to that of the conductive portion 101 of the signal electrode 104. The first flat portion 402 may be disposed between the signal electrode 104 and the ground electrode 106. The second flat portion 404 may face the first flat portion 402, with the signal electrode 104 being interposed therebetween. The first and second flat portions 402, 404 may extend from the insulating plate 120 through the insulating film 130 to the outside of the insulating film 130. The third flat portion 406 may be disposed at the ends of the first and second flat portions 402, 404 outside the insulating film 130. Thus, the three flat portions 402 to 406 may be disposed parallel to the three sides of the signal electrode 104, except the surface of the signal electrode 104 on the insulating plate 120 side.

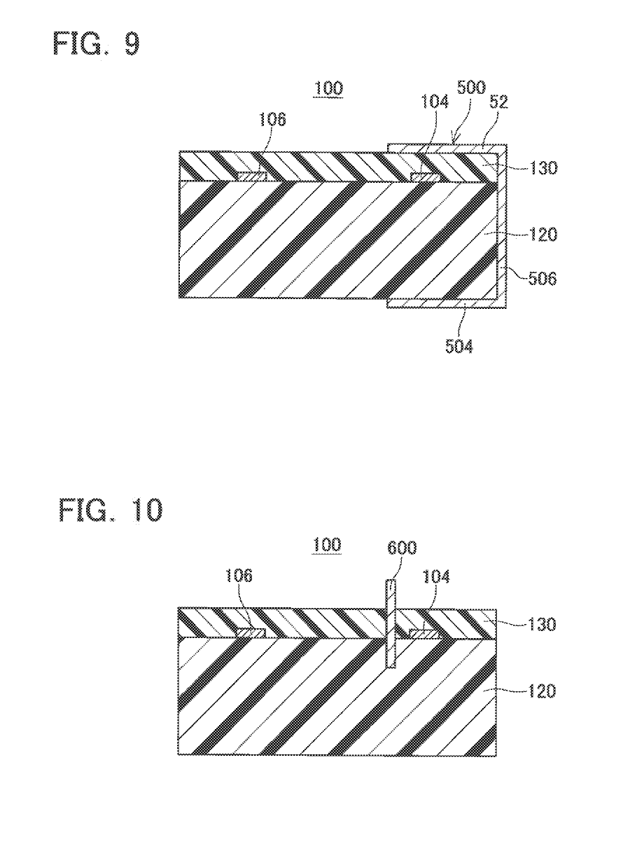

(4) As shown in FIG. 9, a shield electrode 500 may be provided instead of the shield electrode 102. The sheet electrode 500 has three flat portions 502 to 506. Each of the three flat portions 502 to 506 may be disposed parallel to the signal electrode 104 of the conductive portion 101. Each of the three flat portions 502 to 506 may have a length substantially equal to that of the conductive portion 101 of the signal electrode 104. The first flat portion 502 may face the signal electrode 104, with the insulating film 130 being interposed therebetween. The first flat portion 502 may be in contact with the insulating film 130 (upper surface in FIG. 9). The second flat portion 504 may face the first flat portion 502, with the insulating film 130, the signal electrode 104, and the insulating plate 120 being interposed therebetween. The second flat portion 504 may be in contact with the insulating plate 120 (lower surface in FIG. 9). The third flat portion 506 may be disposed at the ends of the first and second flat portions 502, 504 on the side opposite that of the ground electrode 106. The third flat portion 506 may be in contact with the side surfaces (right surfaces in FIG. 9) of the insulating plate 120 and the insulating film 130.

(5) As shown in FIG. 10, a shield electrode 600 may be provided instead of the shield electrode 102. The shield electrode 600 may be a flat plate disposed between the signal electrode 104 and the ground electrode 106. The shield electrode 600 may have a length substantially equal to that of the conductive portion 101 of the signal electrode 104. The shield electrode 600 may extend from the insulating plate 120 through the insulating film 130 to the outside of the insulating film 130.

The abovementioned shield electrodes 300 to 600 may input signals from the oscillating circuits 4, 6 identical to the signal electrode 104, in the same manner as in the case of the shield electrode 102.

(6) The calculating unit 40 may also calculate the resistance value R3 of the mixed fuel in addition of the capacitance C1. The resistance value R3 may be calculated by solving) R3=1/((1/Z1)²−(ω1×C1)^{1/2}. Further, the calculating unit 40 may store in advance a degradation degree database in which the resistance values of mixed fuels are associated with the degradation (oxidation) degree of the mixed fuels (e.g., any of “good”, “small degradation”, and “large degradation (cannot be used)”). Thus, the manufacturer of the sensor system 2 may create the degradation database and store the created database in advance in the calculating unit 40.

(7) In the liquid sensor 10 of the abovementioned embodiment, the electrode unit 100 comprises the first electrode pair 103 and the second electrode pair 117. However, the electrode unit 100 may comprise only with the first electrode pair 103 and not comprise the second electrode pair 117. In this case, the capacitance C1 (in the present variant, equal to the capacitance C2 of the first electrode pair 103) of the electrode unit 100 may be calculated without affecting the resistance value of the mixed fuel.

In order to increase the capacitance C1 of the electrode unit 100, the electrode unit 100 comprises the second electrode pair 117 disposed in parallel with the first electrode pair 103. As a result, the effect produced by the resistance value (conductivity) of the mixed fuel on the output voltage outputted from the electrode unit 100 is decreased. When the ethanol concentration in the mixed fuel is determined using the liquid sensor 10, in a case where the capacitance C3 of the second electrode pair 117 is increased, it is possible to determine easily the ethanol concentration by supplying only a high-frequency (e.g. 500 kHz to 10 MHz) signal to the electrode unit 100.

The technical features explained in the detailed description of the invention or the drawings demonstrate technical utility individually or in various combinations thereof and are not limited to the combinations set forth in the claims at the time of filing. Further, the technique illustrated by way of examples in the detailed description of the invention or the drawings can attain a plurality of objects at the same time, and technical utility is demonstrated by merely attaining one object therefrom.

What is claimed is:

1. A liquid sensor for detecting a liquid property, the liquid sensor comprising:
an electrode unit comprising a first electrode pair to be disposed within liquid; and
a calculating unit configured to calculate a capacitance of the electrode unit by using an output signal outputted from the electrode unit, wherein
the electrode unit is configured capable of respectively connecting with a first oscillating unit and a second oscillating unit,
the first oscillating unit is configured to output a first frequency signal having an amplitude of Vin1 and an angular velocity of ω1,
the second oscillating unit is configured to output a second frequency signal having an amplitude of Vin2 and an angular velocity of ω2, and
the calculating unit calculates a capacitance C1 of the electrode unit by solving a below formula:
$$C 1 = \sqrt{\frac{\frac{1}{Z {1}^{2}} - \frac{1}{Z {2}^{2}}}{( ω {1}^{2} - ω {2}^{2} )}}$$
where
Z1=R1/(Vin1/Vout1−1),
Z2=R2/(Vin2/Vout2−1),
Vout1 is an amplitude of the first output signal,
Vout2 is an amplitude of the second output signal,
R1 is a resistance value between the electrode unit and the first oscillating unit, and
R2 is a resistance value between the electrode unit and the second oscillating unit.

2. The liquid sensor as in claim 1, further comprising:
a first resistor disposed between the first oscillating unit and the electrode unit, and having the resistance value R1; and
a second resistor disposed between the second oscillating unit and the electrode unit, and having the resistance value R2 that is different from the R1.

3. The liquid sensor as in claim 2, wherein:
the resistance value R1 is larger than the resistance value R2.

4. The liquid sensor as in claim 3, wherein
the electrode unit further comprises a second electrode pair,
the first electrode pair and the second electrode pair are layered,
one of the second electrode pair is connected with one of the first electrode pair, and
the other of the second electrode pair is connected with the other of the first electrode pair.

5. The liquid sensor as in claim 4, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.

6. The liquid sensor as in claim 3, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.

7. The liquid sensor as in claim 2, wherein
the electrode unit further comprises a second electrode pair,
the first electrode pair and the second electrode pair are layered,
one of the second electrode pair is connected with one of the first electrode pair, and
the other of the second electrode pair is connected with the other of the first electrode pair.

8. The liquid sensor as in claim 7, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.

9. The liquid sensor as in claim 2, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.

10. The liquid sensor as in claim 1, wherein:
the resistance value R1 is larger than the resistance value R2.

11. The liquid sensor as in claim 10, wherein
the electrode unit further comprises a second electrode pair,
the first electrode pair and the second electrode pair are layered,
one of the second electrode pair is connected with one of the first electrode pair, and
the other of the second electrode pair is connected with the other of the first electrode pair.

12. The liquid sensor as in claim 11, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.

13. The liquid sensor as in claim 10, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.

14. The liquid sensor as in claim 1, wherein
the electrode unit further comprises a second electrode pair,
the first electrode pair and the second electrode pair are layered,
one of the second electrode pair is connected with one of the first electrode pair, and
the other of the second electrode pair is connected with the other of the first electrode pair.

15. The liquid sensor as in claim 14, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.

16. The liquid sensor as in claim 1, further comprising:
a shield electrode disposed adjacent to an electrode of the first electrode pair that is connected to at least one oscillating unit of the first oscillating unit, the second oscillating unit or a combination thereof, wherein
the shield electrode is configured to be connected to the one oscillating unit without any resistance unit intervened between the shield electrode and the one oscillating unit.
